(19) United States
(12) Patent Application Publication
(10) Pub. No.: US 2023/0299085 A1
(43) Pub. Date: Sep. 21, 2023

(54) STACKED TRANSISTORS HAVING MULTIPLE THRESHOLD VOLTAGES

(71) Applicant: INTERNATIONAL BUSINESS MACHINES CORPORATION, ARMONK, NY (US)

(72) Inventors: Ruilong Xie, Niskayuna, NY (US); Nicolas Jean Loubet, GUILDERLAND, NY (US); Julien Frougier, Albany, NY (US); Dechao Guo, Niskayuna, NY (US)

(21) Appl. No.: 17/655,561

(22) Filed: Mar. 21, 2022

(51) Int. Cl. H01L 27/092; H01L 29/06; H01L 29/423; H01L 29/49; H01L 29/78; H01L 29/786; H01L 21/02; H01L 21/8238; H01L 29/66

(52) U.S. Cl. CPC H01L 27/0922; H01L 27/0924; H01L 29/0665; H01L 29/42392; H01L 29/4908; H01L 29/785; H01L 29/78696; H01L 21/0259; H01L 21/823807; H01L 21/823821; H01L 21/823857; H01L 29/66795; H01L 29/66545; H01L 29/66553; H01L 29/66742

(57) ABSTRACT

A semiconductor structure including a first stacked transistor structure including a top device stacked directly above a bottom device, and a second stacked transistor structure adjacent to the first stacked transistor, the second stacked transistor including a top device stacked directly above a bottom device, where the top device of the first stacked transistor structure and the top device of the second stacked transistor structure are made from different gate dielectric materials, and where the bottom device of the first stacked transistor structure and the bottom device of the second stacked transistor structure are made from different gate dielectric materials.

### BACKGROUND

The present invention generally relates to semiconductor structures, and more particularly to stacked transistor structures having multiple threshold voltages.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate-all-around technology. One example of a complex gate-all-around technology is a complementary FET (CFET) where nFET and pFET nanowires/nanosheets are vertically stacked on top of each other.

### SUMMARY

According to an embodiment of the present invention, a semiconductor structure is provided. The semiconductor structure may include a first stacked transistor structure including a top device stacked directly above a bottom device, and a second stacked transistor structure adjacent to the first stacked transistor, the second stacked transistor including a top device stacked directly above a bottom device, where the top device of the first stacked transistor structure and the top device of the second stacked transistor structure are made from different gate dielectric materials, and where the bottom device of the first stacked transistor structure and the bottom device of the second stacked transistor structure are made from different gate dielectric materials.

According to another embodiment of the present invention, a semiconductor structure is provided. The semiconductor structure may include a first stacked transistor structure including a top device stacked directly above a bottom device, and a second stacked transistor structure adjacent to the first stacked transistor, the second stacked transistor including a top device stacked directly above a bottom device, where uppermost surfaces of gate structures for each of the top device of the first stacked transistor structure, the top device of the second stacked transistor structure, the bottom device of the first stacked transistor structure, and the bottom device of the second stacked transistor structure are substantially flush with one another.

According to another embodiment of the present invention, a semiconductor structure is provided. The semiconductor structure may include a stacked transistor structure including a top device stacked directly above a bottom device, where the top device includes a different threshold voltage than the bottom device, and where an uppermost surface of a gate metal for the top device is substantially flush with an uppermost surface of a gate metal for the bottom device.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of a semiconductor structure during an intermediate step of a method of fabricating a stacked transistor structure according to an exemplary embodiment;

FIGS. 4 and 5 are cross-sectional views of the semiconductor structure after forming a bottom sacrificial gate, bottom gate spacers, bottom inner spacers, bottom source drain regions, a bottom dielectric material, and bottom gate cut insulators according to an exemplary embodiment;

FIGS. 6 and 7 are cross-sectional views of the semiconductor structure after forming a first bonding layer and bonding another semiconductor wafer to the structure according to an exemplary embodiment;

FIGS. 8 and 9 are cross-sectional views of the semiconductor structure after forming a top sacrificial gate, top gate spacers, top source drain regions, a top dielectric material, and top gate cut insulators according to an exemplary embodiment;

FIGS. 10 and 11 are cross-sectional views of the semiconductor structure after forming openings, removing both the bottom sacrificial gate and the top sacrificial gate, removing the silicon germanium sacrificial nanosheets, and forming a gate dielectric layer according to an exemplary embodiment;

FIGS. 12 and 13 are cross-sectional views of the semiconductor structure after forming a primary gate dielectric layer according to an exemplary embodiment;

FIGS. 14 and 15 are a cross-sectional views of the semiconductor structure after forming an oxide layer and a capping layer according to an exemplary embodiment;

FIGS. 16 and 17 are cross-sectional views of the semiconductor structure after forming a mask and removing portions of the oxide layer and the capping layer according to an exemplary embodiment;

FIGS. 18 and 19 are cross-sectional views of the semiconductor structure after performing a drive anneal to convert portions of the primary gate dielectric layer into a secondary gate dielectric according to an exemplary embodiment;

FIGS. 20 and 21 are cross-sectional views of the semiconductor structure after forming functional gates according to an exemplary embodiment;

FIGS. 22 and 23 are cross-sectional views of the semiconductor structure after forming contact structures according to an exemplary embodiment;

FIG. 24 is cross-sectional views of the semiconductor structure after forming contact structures according to an alternative embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, or stacked transistors, have known advantages over conventional transistor structures in terms of density, performance, power consumption, and integration. However, fabricating stacked transistor devices with varying threshold voltages presents unique challenges. More specifically, for example, current fabrication techniques do not allow for individual selection of different gate dielectric materials and gate metal materials thus enable individual devices in the stacked architecture to have different threshold voltages.

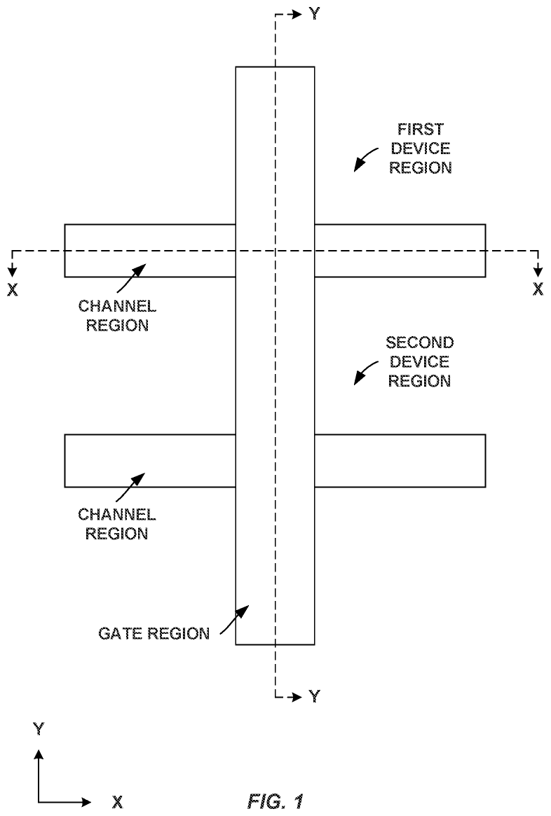

The present invention generally relates to semiconductor structures, and more particularly to stacked transistor structures having multiple threshold voltages. More specifically, the stacked transistor structures and associated method disclosed herein enables a novel solution for providing stacked transistors having multiple threshold voltages. Exemplary embodiments of stacked transistors having multiple threshold voltages are described in detail below by referring to the accompanying drawings in FIGS. 1 to 24. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first device region adjacent to a second device region, channel regions of each, and a single gate region situated perpendicular to the channel regions. FIGS. 1-24 represent cross section views oriented as indicated in FIG. 1.

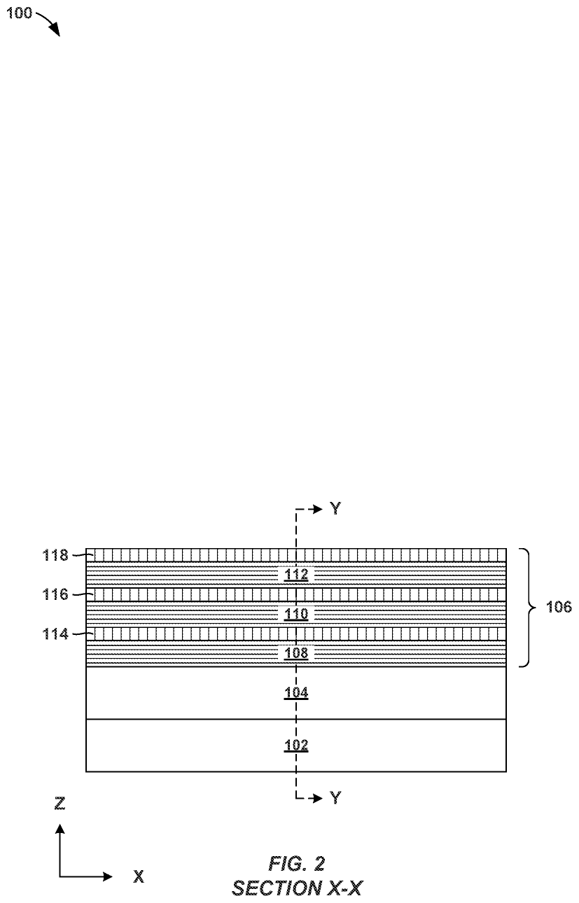

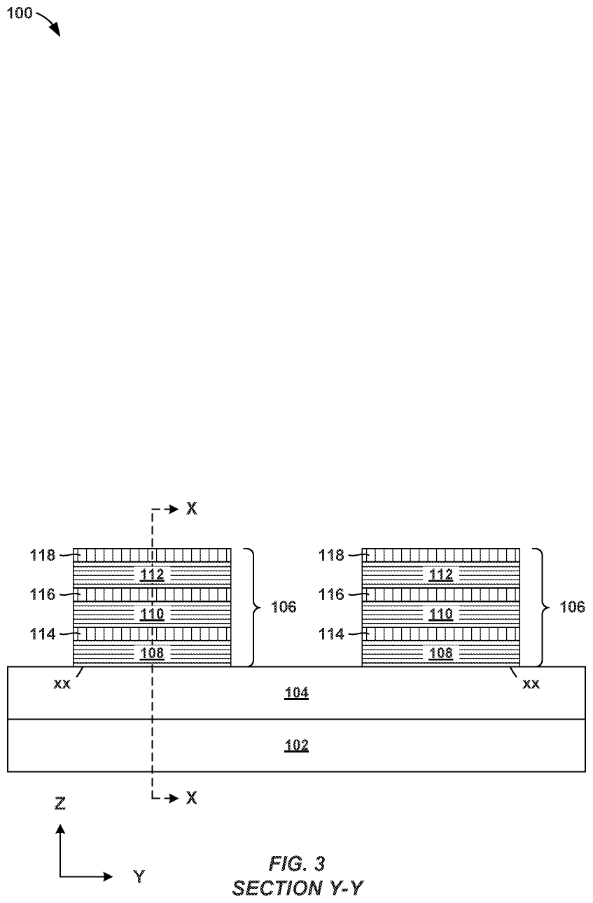

Referring now to FIGS. 2 and 3, a structure 100 is shown during an intermediate step of a method of fabricating a stacked transistor structure according to an embodiment of the invention. FIG. 2 depicts a cross-sectional view of the structure 100 shown in FIG. 3 taken along line X-X, and FIG. 3 depicts a cross-sectional view of the structure 100 shown in FIG. 2 taken along line Y-Y.

The structure 100 illustrated in FIGS. 2 and 3 include nanosheet stacks 106 formed from an alternating series of silicon germanium (SiGe) sacrificial nanosheets 108, 110, 112 and silicon (Si) channel nanosheets 114, 116, 118. The nanosheet stacks 106 are formed on an oxide isolation layer 104, which is formed on a silicon substrate 102. Although only six alternating nanosheets 108, 110, 112, 114, 116, 118 are shown, one or more additional sacrificial nanosheets and/or channel nanosheets can optionally be epitaxially grown in an alternating fashion, and the properties of any additional nanosheets are the same as the corresponding nanosheets described herein.

In one or more embodiments, the alternating series of silicon germanium sacrificial nanosheets 108, 110, 112 and silicon channel nanosheets 114, 116, 118 are formed by epitaxially growing one layer and then the next until a desired number and a desired thicknesses of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, each nanosheet stack 106 includes some combination of silicon channel nanosheets 114, 116, 118 undoped.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

Known processing techniques have been applied to the alternating series of silicon germanium sacrificial nanosheets 108, 110, 112 and silicon channel nanosheets 114, 116, 118 shown in FIGS. 2 and 3 to form the nanosheet stack 106. For example, the known processing techniques can include the formation of hard masks (not shown) over the silicon channel nanosheet 118. The hard masks can be formed by first depositing the hard mask material (for example silicon nitride) onto the top silicon channel nanosheet 118 using, for example, chemical vapor deposition (CVD), plasma enhanced CVD (PECVD) or any suitable technique for dielectric deposition that does not induce a physical or chemical change to silicon channel nanosheet 118. According to an exemplary embodiment, the hard mask material is deposited onto the top silicon channel 118 and then patterned into a plurality of the individual hard masks. Patterning the hard mask is commensurate with a desired footprint and location of the channel nanosheet stacks 106 shown in FIG. 3, which will subsequently be used to form the channel regions of the semiconductor devices disclosed herein. According to an exemplary embodiment, RIE is used to transfer the hard mask pattern into the alternating silicon and silicon germanium layers to form the nanosheet stacks 106.

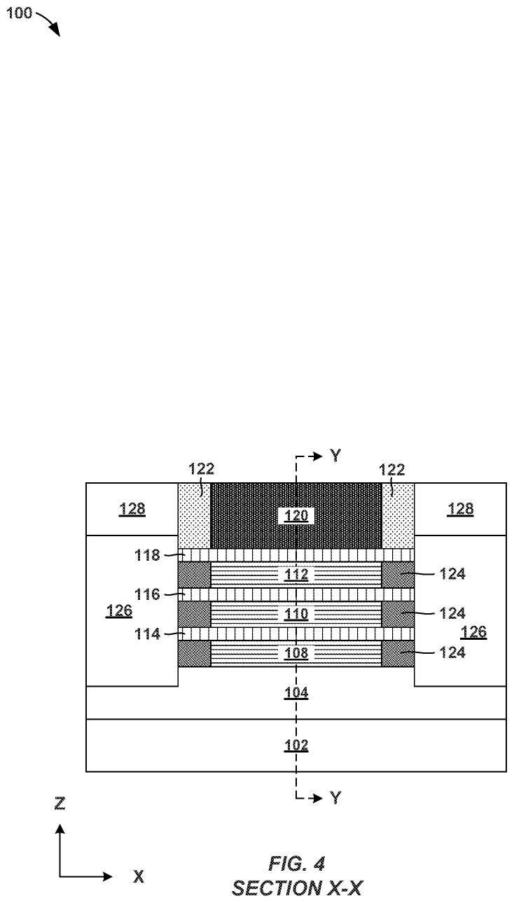

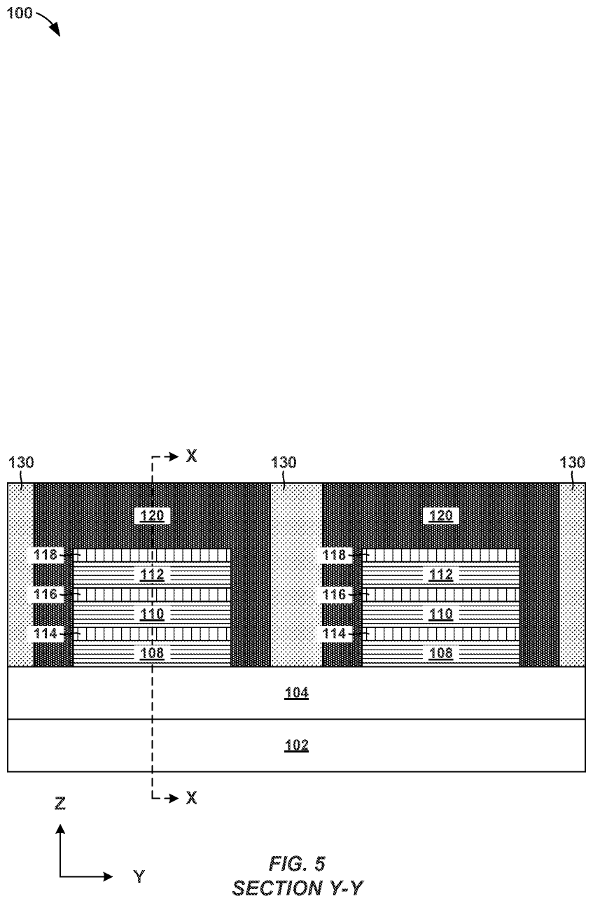

Referring now to FIGS. 4 and 5, the structure 100 is shown after forming a bottom sacrificial gate 120, bottom gate spacers 122, bottom inner spacers 124, bottom source drain regions 126, a bottom dielectric material 128, and bottom gate cut insulators 130 (hereinafter “bottom insulators 130”) according to an embodiment of the invention. FIG. 4 depicts a cross-sectional view of the structure 100 shown in FIG. 5 taken along line X-X, and FIG. 5 depicts a cross-sectional view of the structure 100 shown in FIG. 4 taken along line Y-Y.

The bottom sacrificial gate 120 is formed over and around the nanosheet gate stacks 106 according to known techniques. As best shown in FIG. 5, the bottom sacrificial gate 120 is formed over the tops and sidewalls of the nanosheet stacks 106. In one or more embodiments, the bottom sacrificial gate 120 is formed from a thin a layer of silicon oxide (SiO2) and amorphous silicon (a-Si). More specifically, a relatively thin layer of silicon oxide is first conformally deposited over and around the nanosheet gate stacks 106 followed by a blanket layer of amorphous silicon.

The bottom gate spacers 122 are formed along the vertical sidewalls of the bottom sacrificial gate 120, as shown. The bottom gate spacers 122 can be formed using known techniques, which includes spacer material deposition followed by directional RIE of the deposited spacer material. A width of the bottom gate spacers 122 are chosen such that the bottom gate spacers 122 and the bottom sacrificial gate 120 define a width of a bottom device.

The bottom gate spacers 122 are in effect used as a mask, and portions of the silicon germanium sacrificial nanosheets 108, 110, 112, the silicon channel nanosheets 114, 116, 118, and the oxide isolation layer 104 that are not protected by the bottom sacrificial gate 120 or the bottom gate spacers 122 are recessed into the oxide isolation layer 104 using a silicon RIE process and form an opening or trench (not shown).

The silicon germanium sacrificial nanosheets 108, 110, 112 are laterally recessed to make room for the bottom inner spacers 124. In one or more embodiments, the silicon germanium sacrificial nanosheets 108, 110, 112 are laterally recessed using a hydrogen chloride (HCL) gas isotropic etch process, which etches silicon germanium without attacking silicon. Cavities (not shown) are formed by spaces that were occupied by the removed portions of silicon germanium sacrificial nanosheets 108, 110, 112.

The bottom inner spacers 124 are formed by first conformally depositing a spacer material over the structure 100 to fill the cavities created by laterally recessing the silicon germanium sacrificial nanosheets 108, 110, 112. ‘As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The conformal spacer material is then isotropically etched to remove all portions except those remaining in the cavities and forming the bottom inner spacers 124. In one or more embodiments, the bottom inner spacers 124 are made from a nitride containing material, for example silicon nitride (SiN). Although bottom inner spacers 124 shown in FIG. 4 are formed from a nitride containing material, they can be formed from any material for which subsequent device fabrication operations are not very selective. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the bottom inner spacers 124 can be selected based on a selectivity of subsequent device fabrication operations for the selected material being below a predetermined threshold.

The bottom inner spacers 124 are positioned such that subsequent etching processes used to remove the silicon germanium sacrificial nanosheets 108, 110, 112 during device fabrication do not also attack subsequently formed source drain regions.

The bottom source drain regions 126 are formed using an epitaxial layer growth process on the exposed ends of the silicon channel nanosheets 114, 116, 118. Typically, in-situ doping is used to doped the bottom source drain regions 126, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a p-type piece of silicon, rich in holes, and an n-type piece of silicon, rich in electrons. N-type and p-type devices are formed by implanting different types of dopants to selected regions of the device to form the necessary junction(s). N-type devices can be formed by implanting arsenic (As) or phosphorous (P), and p-type devices can be formed by implanting boron (B).

The bottom dielectric material 128 is formed by depositing an interlayer dielectric material over the structure 100 according to known techniques. The bottom dielectric material 128 is formed on the source drain regions 126. After, the bottom dielectric material 128 can be polished using known techniques until a topmost surface of the bottom dielectric material 128 is flush, or substantially flush, with topmost surfaces of the bottom sacrificial gate 120 and the bottom gate spacers 122.

The bottom dielectric material 128 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. In another embodiment, a self-planarizing material such as a spin-on glass (SOG) or a spin-on low-k dielectric material such as SiLK™ can be used as the bottom dielectric material 128. Using a self-planarizing dielectric material as the bottom dielectric material 128 can avoid the need to perform a subsequent planarizing step.

Finally, a gate cut mask (not shown) is formed over the structure 100 and exposed portions of the bottom sacrificial gate 120 are removed and then filled with a dielectric insulating material to form the bottom insulators 130. The gate cut mask, and subsequently the bottom insulators 130, define gate regions of individual bottom devices.

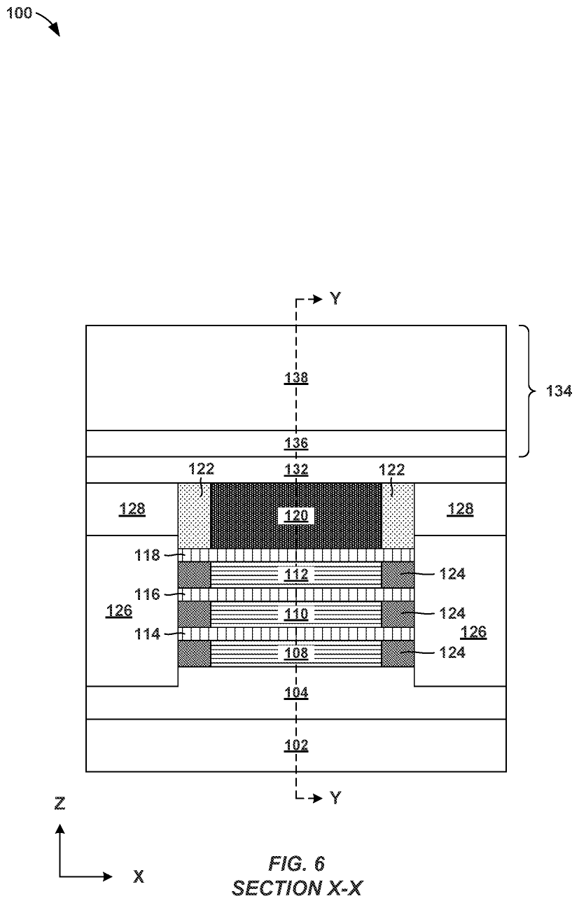

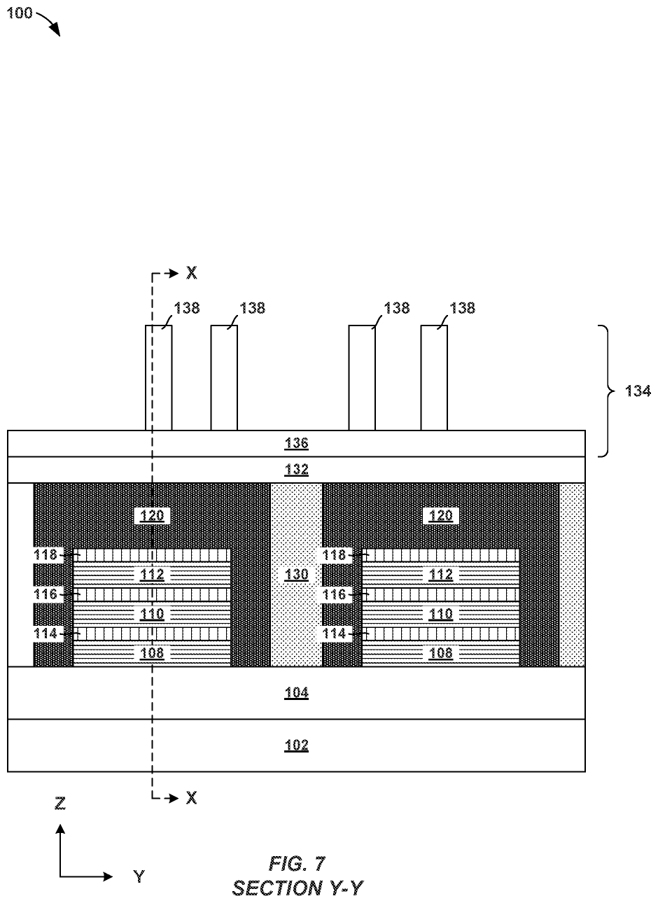

Referring now to FIGS. 6 and 7, the structure 100 is shown after bonding a top semiconductor channel material to the structure 100 according to an embodiment of the invention. FIG. 6 depicts a cross-sectional view of the structure 100 shown in FIG. 7 taken along line X-X, and FIG. 7 depicts a cross-sectional view of the structure 100 shown in FIG. 6 taken along line Y-Y.

According to the present embodiment, an additional wafer 134 is bonded to the existing structure 100 of FIGS. 4 and 5 using a conventional dielectric-to-dielectric bonding process, for example, oxide-to-oxide bonding. Specifically, a first bonding oxide layer 132 can be blanket deposited over the existing structure, as shown, and the additional wafer 134, including a second bonding oxide layer 136 and a semiconductor substrate, is then attached to the existing structure 100 using known oxide-to-oxide bonding techniques.

In practice, the wafer 134 is flipped so as to permit face-to-face bonding of the first bonding layer 132 to the second bonding layer 136. For example, an oxide-to-oxide bond is formed between the first bonding layer 132 and the second bonding layer 136. The bonding process is performed by pressing the bonding layers (132, 136) together, for example face-to-face, at room temperature with a force initiating from a center contacting area. The contacting area will expand from the center outward across the layers. Thereafter, a thermal anneal at 280 degrees Celsius (° C.) for greater than about 12 hours, e.g., for about 24 hours, is required to enforce the bonding quality.

After bonding, the semiconductor substrate of the additional wafer 134 is thinned or recessed to a desired thickness. In at least one embodiment, the additional wafer 134 may further include one or more etch stop layers, for example silicon germanium, to facilitate thinning the semiconductor substrate to the desired thickness. After thinning, and with continued reference to FIGS. 6 and 7, fins 138 are formed from the remaining substrate layer according to known techniques. The fins 138 will form the channel regions of top devices in a stacked transistor configuration as described in greater detail below.

Although the structure 100 is illustrated with a discrete number of fins 138, it may include any number of fins 138 in any number of configurations, as desired by the final design.

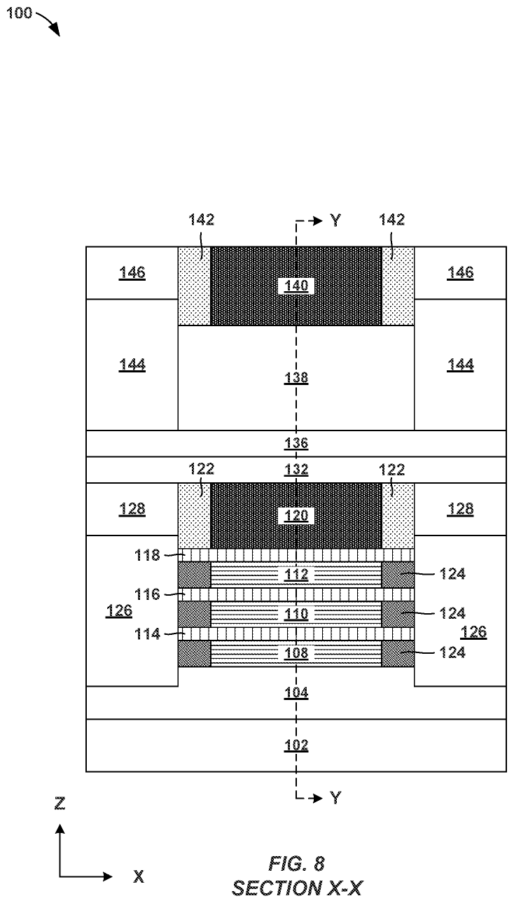

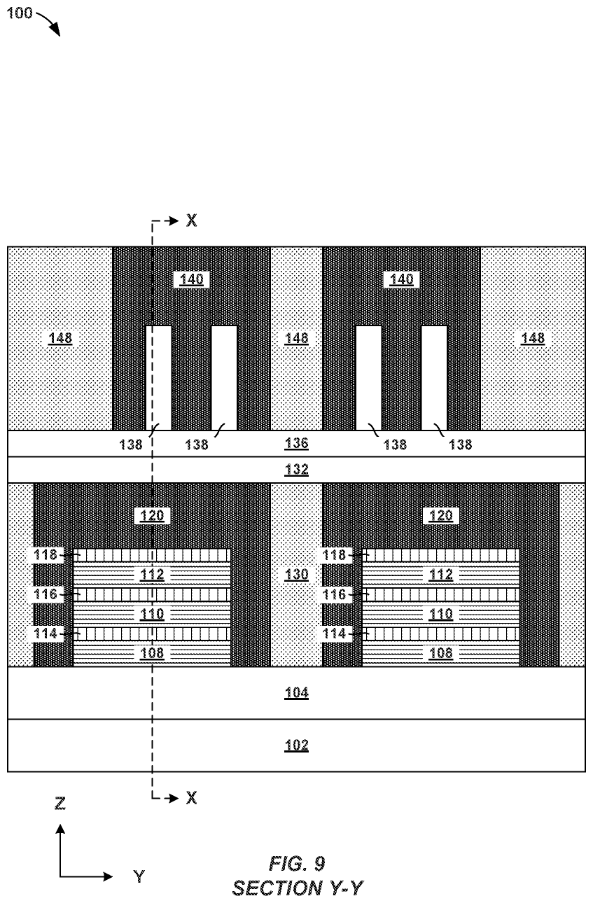

Referring now to FIGS. 8 and 9, the structure 100 is shown after forming a top sacrificial gate 140, top gate spacers 142, top source drain regions 144, a top dielectric material 146, and top gate cut insulators 148 (hereinafter “top insulators 148”) according to an embodiment of the invention. FIG. 8 depicts a cross-sectional view of the structure 100 shown in FIG. 9 taken along line X-X, and FIG. 9 depicts a cross-sectional view of the structure 100 shown in FIG. 8 taken along line Y-Y.

The top sacrificial gate 140 is formed over and around the fins 138 according to known techniques. As best shown in FIG. 9, the top sacrificial gate 140 is formed over the tops and sidewalls of the fins 138. The top sacrificial gate 140 is formed in a similar manner and with similar materials as the bottom sacrificial gate 120 described above.

The top gate spacers 142 are formed in a similar manner and with similar materials as the bottom gate spacers 122 described above. The top gate spacers 142 are formed along the vertical sidewalls of the top sacrificial gate 140, as shown. A width of the top gate spacers 142 is chosen such that the top gate spacers 142 and the top sacrificial gate 140 define a width of a top device.

Also like above, the top gate spacers 142 are in effect used as a mask, and portions of the fins 138 that are not protected by the top sacrificial gate 140 or the top gate spacers 142 are recessed using a silicon RIE process and form an opening or trench (not shown). In at least one embodiment, recessing continues until the second bonding layer 136 is exposed.

The top source drain regions 144 are formed in a similar manner and with similar materials as the bottom source drain regions 126 described above. Like the bottom source drain regions 126 described above, the top source drain regions 144 are formed using an epitaxial layer growth process on the exposed ends of the fins 138 within the opening created by recessing portions of the fins 138.

The top dielectric material 146 are formed in a similar manner and with similar materials as the bottom dielectric material 128 described above. Like the bottom dielectric material 128 described above, the top dielectric material 146 is formed by depositing an interlayer dielectric material over the structure 100 according to known techniques. The top dielectric material 146 is formed on the top source drain regions 144. After, the top dielectric material 146 can be polished using known techniques until a topmost surface of the top dielectric material 146 is flush, or substantially flush, with topmost surfaces of the top sacrificial gate 140 and the top gate spacers 142.

Finally, a gate cut mask (not shown) is formed over the structure 100 and exposed portions of the top sacrificial gate 140 are removed and then filled with a dielectric insulating material to form the top insulators 148. The gate cut mask, and subsequently the top insulators 148, define gate regions of individual top devices.

A critical feature of the present invention is the difference between the gate cut of the bottom sacrificial gate 120 and the gate cut of the top sacrificial gate 140.

As evident in FIG. 9, and critical to the present invention, the top sacrificial gate 140 is laterally smaller than the bottom sacrificial gate 120. The lateral dimensions of the bottom sacrificial gate 120 and the top sacrificial gate 140 is controlled by the corresponding gate mask used. As discussed in greater detail below, such a configuration enables certain objects of the present invention which otherwise may not be possible if the top sacrificial gate 140 is not laterally smaller than the bottom sacrificial gate 120.

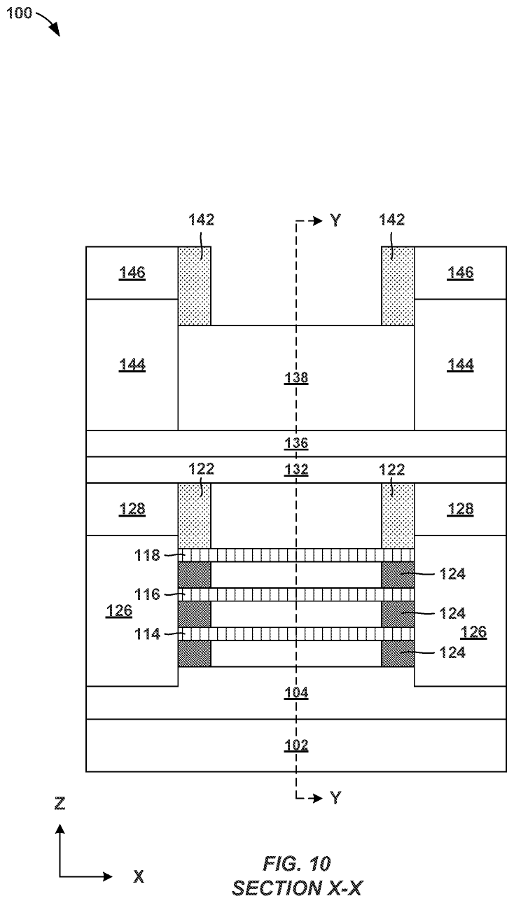

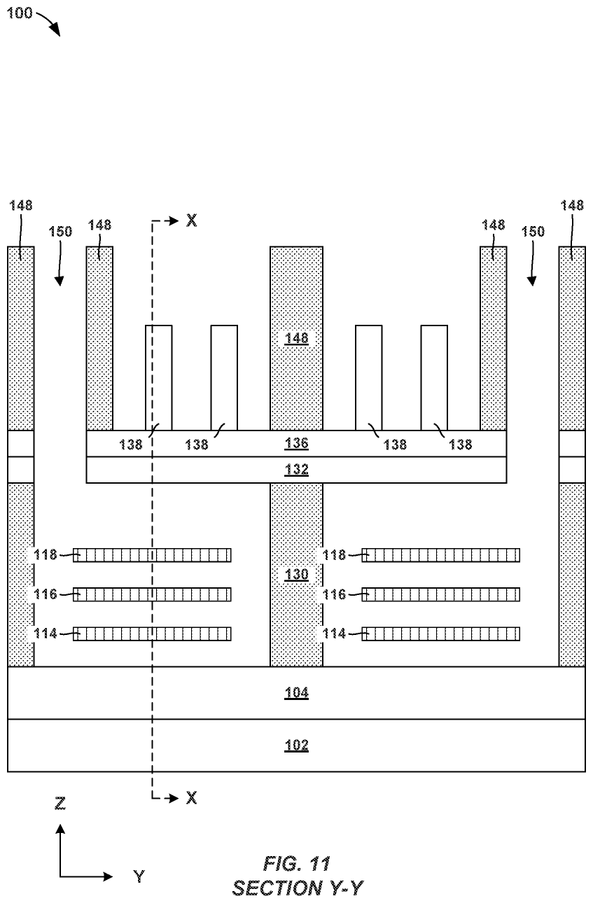

Referring now to FIGS. 10 and 11, the structure 100 is shown after forming openings 150, removing both the bottom sacrificial gate 120 and the top sacrificial gate 140, and removing the silicon germanium sacrificial nanosheets 108, 110, 112 according to an embodiment of the invention. FIG. 10 depicts a cross-sectional view of the structure 100 shown in FIG. 11 taken along line X-X, and FIG. 11 depicts a cross-sectional view of the structure 100 shown in FIG. 10 taken along line Y-Y.

The access openings 150 are formed through the top insulators 148 and are specifically designed to expose uppermost surfaces of the bottom sacrificial gate 120. The access openings 150 may be formed using masking and etching techniques known in the art. In practice, an anisotropic etching technique is commonly used to create the access openings 150.

Forming the access openings 150 to expose the uppermost surfaces of the bottom sacrificial gate 120 might not be possible if, for example, the top sacrificial gate 140 was not laterally smaller than the bottom sacrificial gate 120, in at least one direction. The access openings 150 are necessary for the subsequent removal of the bottom sacrificial gate 120 and later formation of any gate materials, as described in greater detail below.

Next, the bottom sacrificial gate 120 and the top sacrificial gate 140 are removed according to known techniques. Specifically, the bottom sacrificial gate 120 is etched or removed relative to the nanosheet stacks 106 and the bottom insulators 130, and the top sacrificial gate 140 is removed or etched selective to the fins 138 and the top insulators 148. For example, the amorphous silicon of both the bottom sacrificial gate 120 and the top sacrificial gate 140 are first removed selective to the relatively thin silicon oxide layer using known wet etching techniques, such as, for example, hot ammonia or TMAH. Next, the relatively thin silicon oxide layer is removed selective to the silicon germanium sacrificial nanosheets 108, 110, 112 and the fins 138 using alternative known wet etching techniques, such as, for example, a diluted hydrofluoric acid (DHF). The relatively thin silicon oxide layer protects the silicon germanium sacrificial nanosheets 108, 110, 112 and the fins 138 during selective removal of the amorphous silicon.

Finally, the silicon germanium sacrificial nanosheets 108, 110, 112 are removed according to known techniques. Specifically, the silicon germanium sacrificial nanosheets 108, 110, 112 are etched or removed selective to the silicon channel nanosheets 114, 116, 118. For example, the silicon germanium sacrificial nanosheets 108, 110, 112 are removed selective to the silicon channel nanosheets 114, 116, 118 according to known wet or dry etching techniques, such as, for example, vapor phased dry HCl etch. After etching, the silicon channel nanosheets 114, 116, 118 remain suspended and supported on opposite ends by the inner spacers 124 and the bottom source drain regions 126.

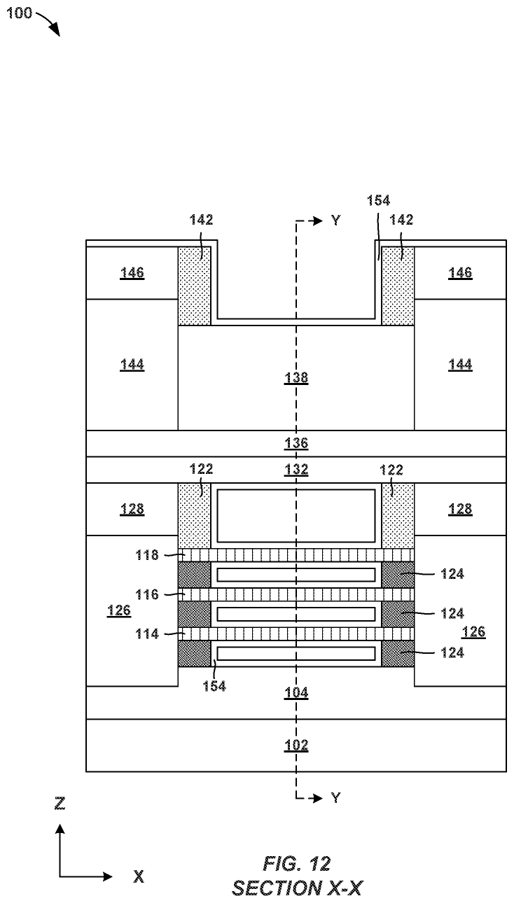

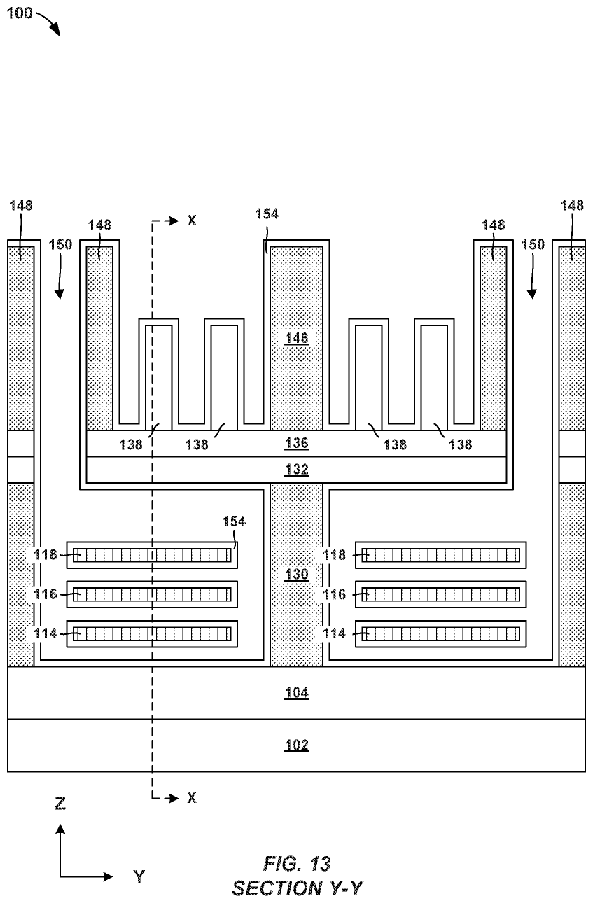

Referring now to FIGS. 12 and 13, the structure 100 is shown after forming a primary gate dielectric layer 154 according to an embodiment of the invention. FIG. 12 depicts a cross-sectional view of the structure 100 shown in FIG. 13 taken along line X-X, and FIG. 13 depicts a cross-sectional view of the structure 100 shown in FIG. 12 taken along line Y-Y.

The primary gate dielectric layer 154 is conformally deposited directly on exposed surfaces within the openings and spaces left by removing the bottom sacrificial gate 120, the top sacrificial gate 140, and the silicon germanium sacrificial nanosheets 108, 110, 112. For example, the primary gate dielectric layer 154 is conformally deposited along exposed surfaces of the fins 138, the top gate cut insulators 148, the second bonding layer 136, the silicon channel nanosheets 114, 116, 118, the bottom cut insulators 1130, and the first bonding layer 132, as best illustrated in FIG. 13. Additionally, the primary gate dielectric layer 154 is conformally deposited along exposed surfaces of the top gate spacers 142, the bottom gate spacers 122, and the inner spacers 124, as best illustrated in FIG. 12.

The gate primary dielectric layer 154 can be formed by any deposition technique including, for example, chemical vapor deposition (CVD), plasma enhanced chemical vapor deposition (PECVD), physical vapor deposition (PVD), sputtering, or atomic layer deposition (ALD). In an embodiment, the primary gate dielectric layer 154 can have a thickness in ranging from approximately 1 nm to approximately 5 nm. Other thicknesses that are lesser than, or greater than, the aforementioned thickness range can also be used for the primary gate dielectric layer 154.

The primary gate dielectric layer 154 is composed of any known gate dielectric materials, for example, oxide, nitride, and/or oxynitride. In an example, the primary gate dielectric layer 154 can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₂, HfOₓN_{y}, ZrOₓN_{y}, La₂OₓN_{y}, A₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the primary gate dielectric layer 154. In at least one embodiment, the primary gate dielectric layer 154 is composed of hafnium oxide.

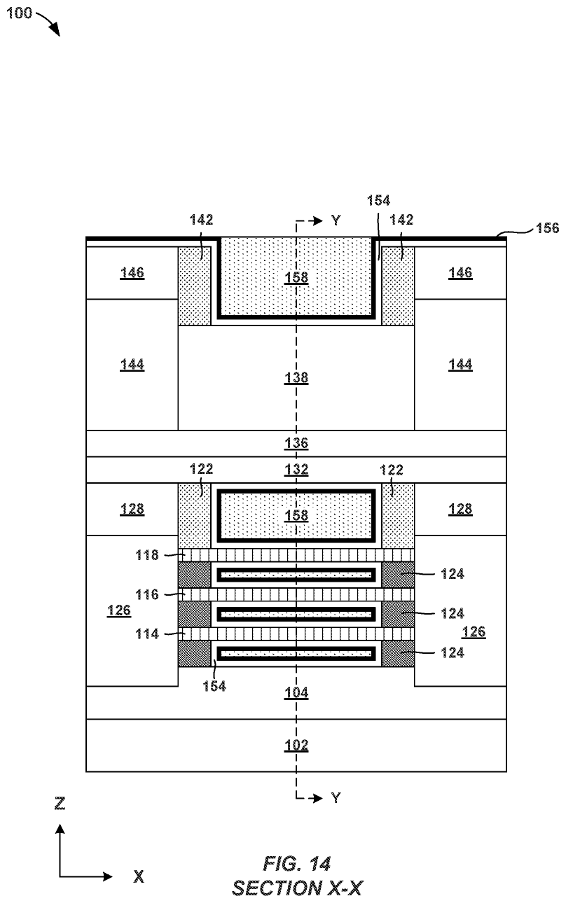

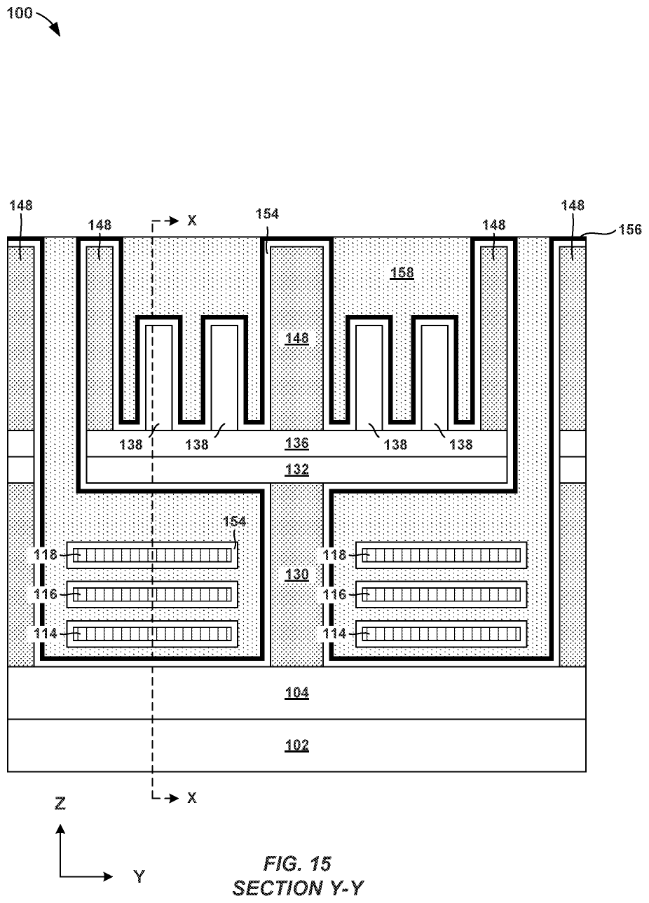

Referring now to FIGS. 14 and 15, the structure 100 is shown after forming an oxide layer 156 and a capping layer 158 according to an embodiment of the invention. FIG. 14 depicts a cross-sectional view of the structure 100 shown in FIG. 15 taken along line X-X, and FIG. 15 depicts a cross-sectional view of the structure 100 shown in FIG. 14 taken along line Y-Y.

The oxide layer 156 is conformally deposited directly on the primary gate dielectric layer 154. The oxide layer 156 can be formed by any deposition technique including, for example, chemical vapor deposition (CVD), plasma enhanced chemical vapor deposition (PECVD), physical vapor deposition (PVD), sputtering, or atomic layer deposition (ALD). In an embodiment, the oxide layer 156 can have a thickness in ranging from approximately 0.3 nm to approximately 2 nm. Other thicknesses that are lesser than, or greater than, the aforementioned thickness range can also be used for the oxide layer 156.

The oxide layer 156 is composed of any known metal oxides which are capable of being subsequently removed selective to the primary gate dielectric layer 154. In at least one embodiment, the oxide layer 156 is made of lanthanum oxide (LaOx). In at least another embodiment, the oxide layer 156 is made of aluminum oxide (AlOx).

The capping layer 158 is blanket deposited over the structure 100 according to known techniques. More specifically, the capping layer 158 is deposited directly on top of the oxide layer 156 and filling the openings and spaces left by removing the bottom sacrificial gate 120, the top sacrificial gate 140, and the silicon germanium sacrificial nanosheets 108, 110, 112. In most case, the capping layer 158 will also be deposited on uppermost surfaces of the structure 100 at large but subsequently removed or polished by known techniques. More specifically, after polishing a topmost surface of the bottom dielectric material 128 is flush, or substantially flush, with topmost surfaces of the capping layer 158 is flush, or substantially flush, with topmost surfaces of the oxide layer 156, as shown.

The capping layer 158 can be composed of any known materials which are capable of being subsequently removed selective to the oxide layer 156. In at least one embodiment, the capping layer 158 is made of a relatively thin titanium nitride layer (TiN) followed by an amorphous silicon (a-Si) fill.

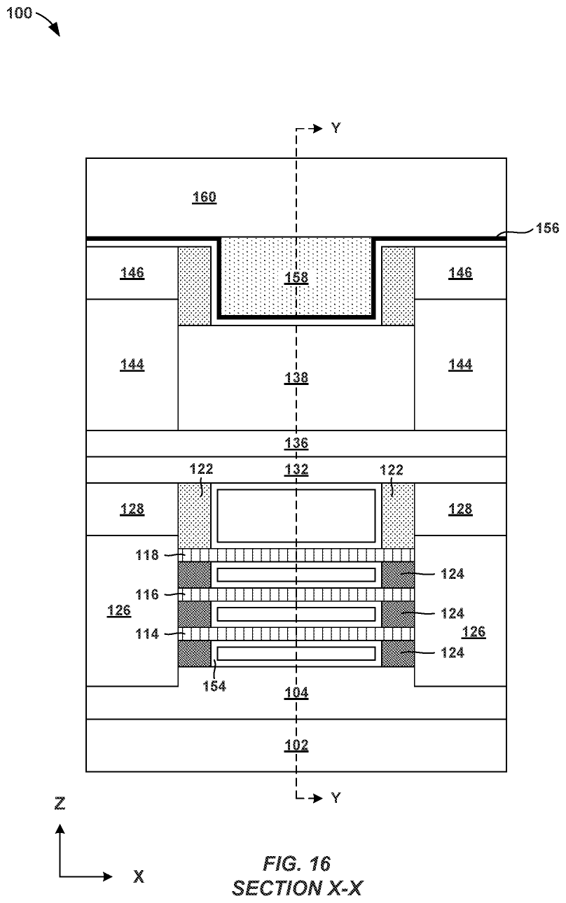

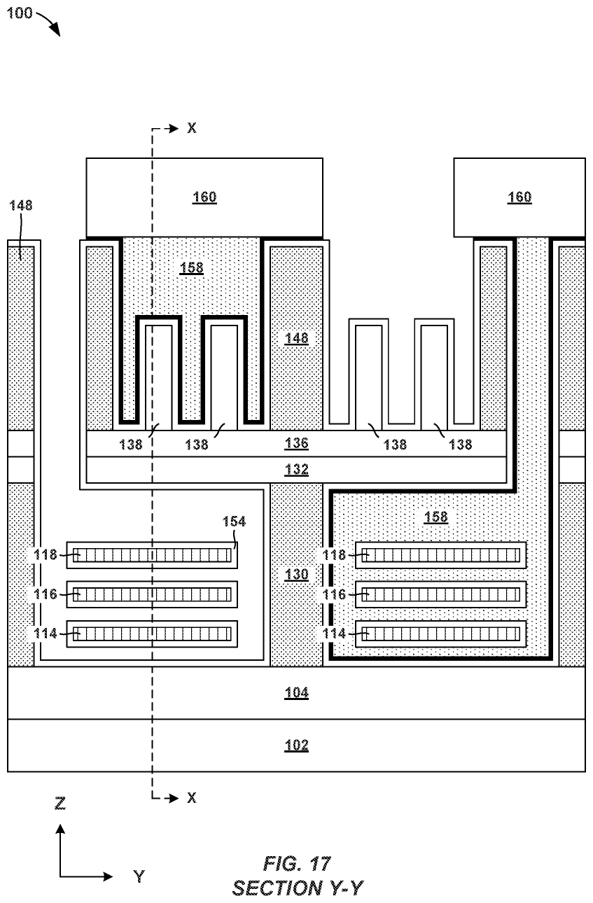

Referring now to FIGS. 16 and 17, the structure 100 is shown after forming a mask 160 and removing portions of the oxide layer 156 and the capping layer 158 according to an embodiment of the invention. FIG. 16 depicts a cross-sectional view of the structure 100 shown in FIG. 17 taken along line X-X, and FIG. 17 depicts a cross-sectional view of the structure 100 shown in FIG. 16 taken along line Y-Y.

First, the mask 160 is deposited and subsequently patterned to expose certain portions of the structure 100 according to known techniques. Specifically, portions of the capping layer 158 surrounding the silicon channel nanosheets 114, 116, 118 on the left and the fins 138 on the right.

The mask 160 can be an organic planarization layer (OPL) or a layer of material that is capable of being planarized or etched by known techniques. In an embodiment, for example, the mask 160 can be an amorphous carbon layer able to withstand subsequent processing temperatures. The mask 160 can preferably have a thickness sufficient to cover existing structures. After deposition of the mask 160, a dry etching technique is applied to pattern the mask 160.

Next, portions of the capping layer 158 are selectively removed according to known techniques. Specifically, portions of the capping layer 158 are removed selective to the oxide layer 156. For example, portions of the capping layer 158 are removed selective to the oxide layer 156 using known etching techniques, suitable to remove the amorphous silicon (a-Si) fill and the relatively thin titanium nitride layer selective to lanthanum oxide or aluminum oxide. In at least one embodiment, an isotropic wet etch, such as diluted HCL or TMAH, is used to selectively remove portions of the capping layer 158. In at least another embodiment, a dry etch, such as reactive ion etching, is used to selectively remove portions of the capping layer 158.

Next, exposed portions of the oxide layer 156 are selectively removed according to known techniques. Specifically, portions of the oxide layer 156 are removed selective to the primary gate dielectric layer 154. For example, portions of the oxide layer 156 are removed selective to the primary gate dielectric layer 154 are removed using known etching techniques suitable to remove lanthanum oxide or aluminum oxide selective to high-k dielectrics such as hafnium oxide. In at least one embodiment, an isotropic wet etch, such as diluted HCL or TMAH, is used to selectively remove exposed portions of the oxide layer 156. In at least another embodiment, a dry etch, such as reactive ion etching, is used to selectively remove exposed portions of the oxide layer 156.

After portions of the oxide layer 156 and the capping layer 158 are selectively removed the mask 160 is removed using known techniques, for example, by ashing.

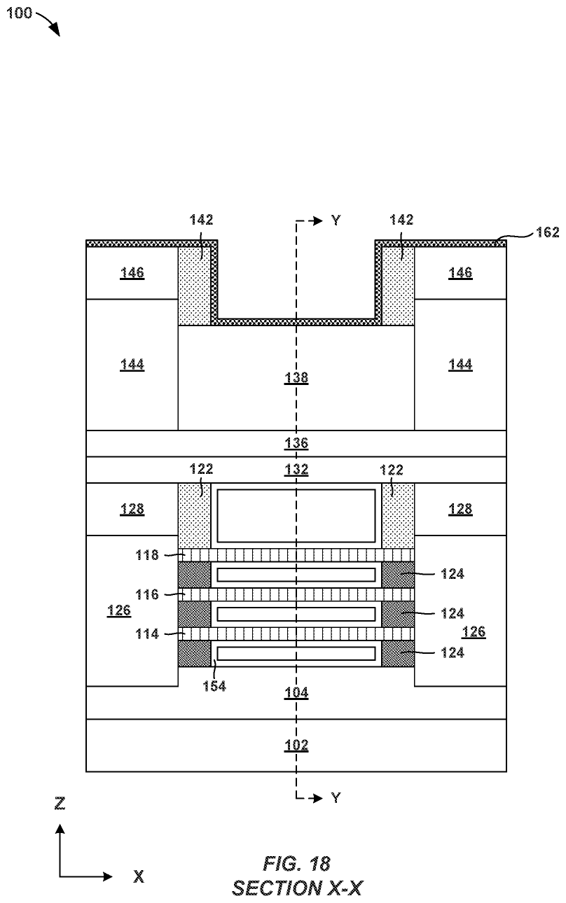

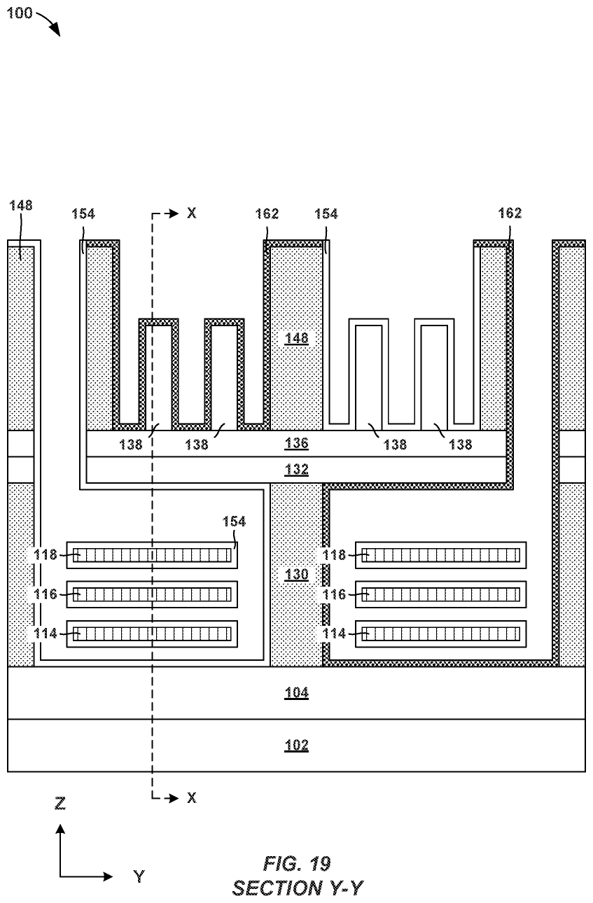

Referring now to FIGS. 18 and 19, the structure 100 is shown after performing a drive anneal to convert portions of the primary gate dielectric layer 154 into a secondary gate dielectric 162 according to an embodiment of the invention. FIG. 18 depicts a cross-sectional view of the structure 100 shown in FIG. 19 taken along line X-X, and FIG. 19 depicts a cross-sectional view of the structure 100 shown in FIG. 18 taken along line Y-Y.

The existing structure 100 is protected with a thin titanium nitride layer followed by an amorphous silicon fill (not shown). First, the thin titanium nitride layer is conformally deposited directly on exposed surfaces of the primary gate dielectric layer 154 and the oxide layer 156 according to known techniques. Next, amorphous silicon is deposited on top of the thin titanium nitride layer according to known techniques. The thin titanium nitride layer amorphous silicon will cover and protect the primary gate dielectric layer 154 and the oxide layer 156 during a subsequent thermal process.

A thermal process, for example an annealing technique, is used to diffuse or drive the oxide layer 156 into the primary gate dielectric layer 154 and form the secondary gate dielectric 162. Stated differently, after the anneal the secondary gate dielectric 162 is composed of both the oxide layer 156 and the primary gate dielectric layer 154. For example, the anneal causes lanthanum oxide of the oxide layer 156 to diffuse into the hafnium oxide of the primary gate dialectic layer 154 and form the secondary gate dielectric 162 made from hafnium lanthanum oxide. In an alternative example, the anneal causes aluminum oxide of the oxide layer 156 to diffuse into the hafnium oxide of the primary gate dialectic layer 154 and form the secondary gate dielectric 162 made from hafnium aluminum oxide. As such, in all cases, the primary gate dielectric layer 154 and the secondary gate dielectric 162 share at least one element.

In an embodiment, for example, the anneal may include subjecting the structure 100 to an elevated temperature ranging from approximately 800° C. to approximately 1250° C., for approximately 1 ms to approximately 500 ms. In yet another embodiment, a high-temperature rapid thermal anneal (RTA) technique may be used, such as, for example, a high temperature spike anneal, or a laser spike anneal. Typically, high temperatures cannot be used at this stage of fabrication due to risk of damaging a gate meal or work function metal; however, in the present case the gate metal or work function metal has not yet been fabricated thus allowing the use of a high temperature anneal.

After the anneal, the titanium oxide layer and amorphous silicon fill are subsequently removed according to known techniques.

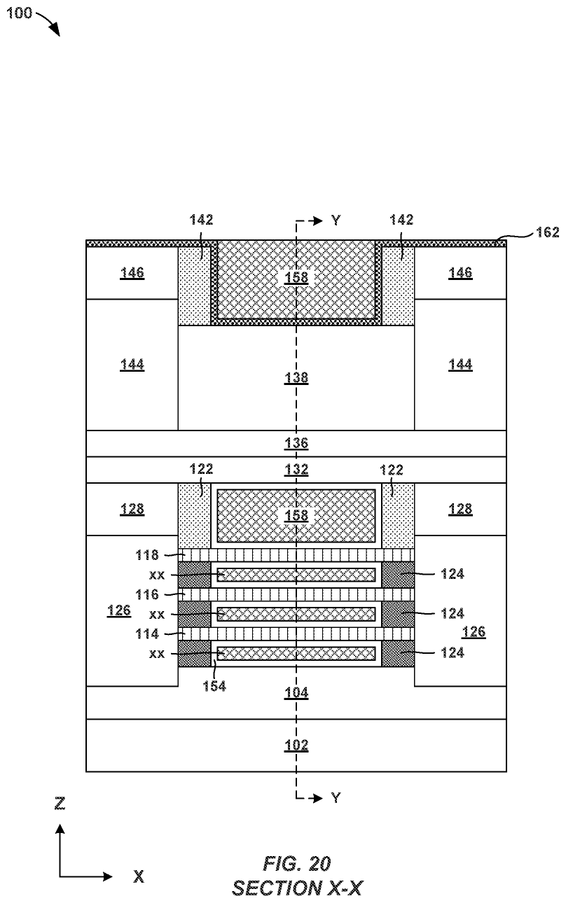

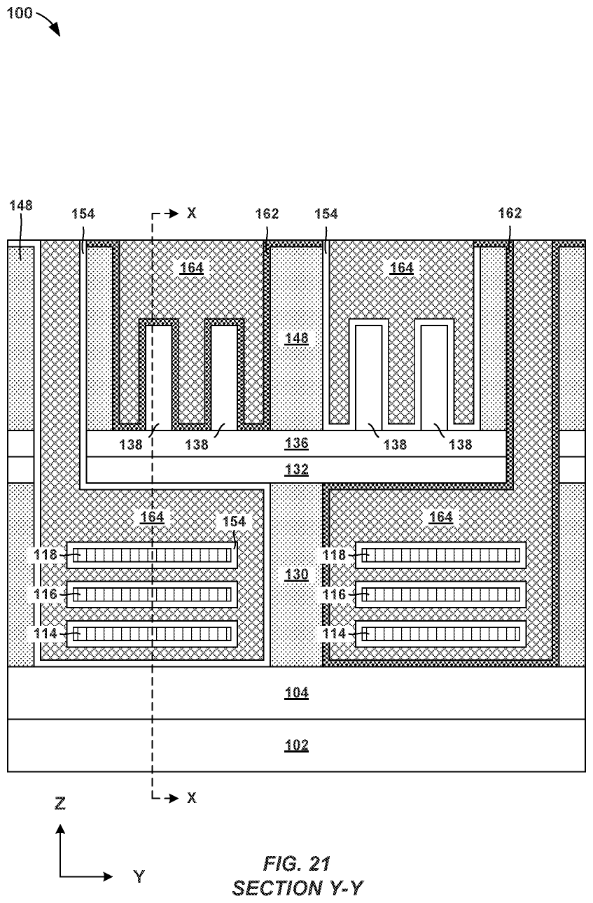

Referring now to FIGS. 20 and 21, the structure 100 is shown after forming functional gates 164 according to an embodiment of the invention. FIG. 20 depicts a cross-sectional view of the structure 100 shown in FIG. 21 taken along line X-X, and FIG. 21 depicts a cross-sectional view of the structure 100 shown in FIG. 20 taken along line Y-Y.

The functional gates 164 is formed within the gate cavities and directly on exposed surfaces of the primary gate dielectric layer 154 and the secondary gate dielectric 162 according to known techniques. More specifically, the functional gates 164 surrounds exposed portions of the silicon channel nanosheets 114, 116, 118 and the fins 138 as shown. As shown, the primary gate dielectric layer 154 and the secondary gate dielectric 162 physically separates the functional gates 164 from the silicon channel nanosheets 114, 116, 118 and the fins 138 as well as the bottom insulators 130, the top insulators 148, the first bonding layer 132, and the second bonding layer 136. By “functional gate structure” it is meant a permanent gate structure used to control output current (i.e., flow of carriers in the channel) of a semiconducting device through electrical or magnetic fields.

In at least one embodiment, the functional gates 164 is made of the same conductive material across the entire structure. In at least another embodiment, the functional gates 164 is made from different conductive materials in each of the four gate cavities. In doing so, the different conductive materials would be deposited successively according to the design parameters and desired operation characteristics.

The functional gates 164 can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium alumunm (TiAl), titanium aluminum cabron (TiAlC), or multilayered combinations thereof. In some embodiments, the functional gates 164 can include an nFET gate metal. In other embodiments, the functional gates 164 can include a pFET gate metal. When multiple gate cavities are formed, as illustrated herein, embodiments of the present invention explicitly contemplate forming an nFET in at least one of the gate cavities and a pFET in at least another one of the gate cavities.

After forming the functional gates 164, excess conductive gate material can be polished using known techniques until a topmost surface of the functional gates 164 are flush, or substantially flush, with topmost surfaces of the primary gate dielectric layer 154 and the secondary gate dielectric 162. Alternatively, in some embodiments, the primary gate dielectric layer 154 and the secondary gate dielectric 162 are also removed during polishing until a topmost surface of each of the functional gates 164, the primary gate dielectric layer 154 and the secondary gate dielectric 162 are flush, or substantially flush, with topmost surfaces of top insulators 148.

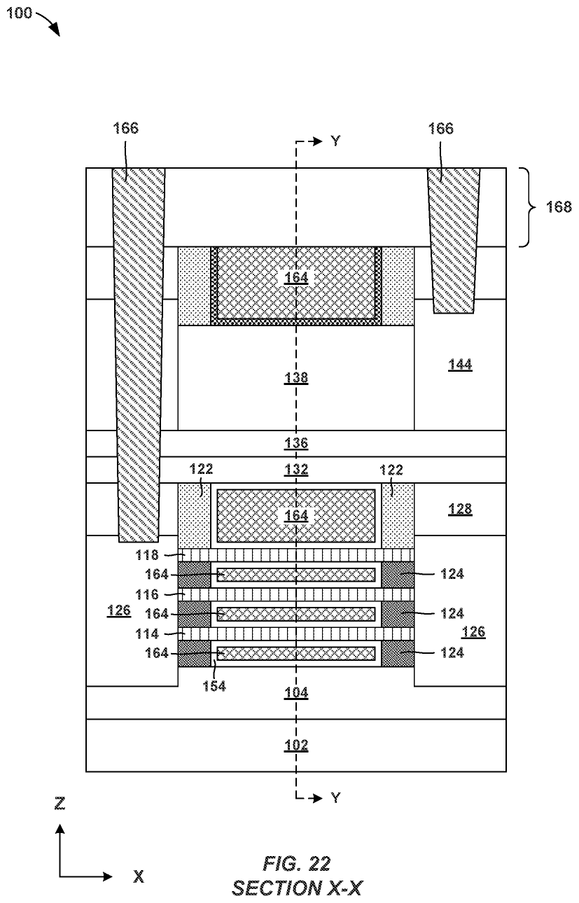

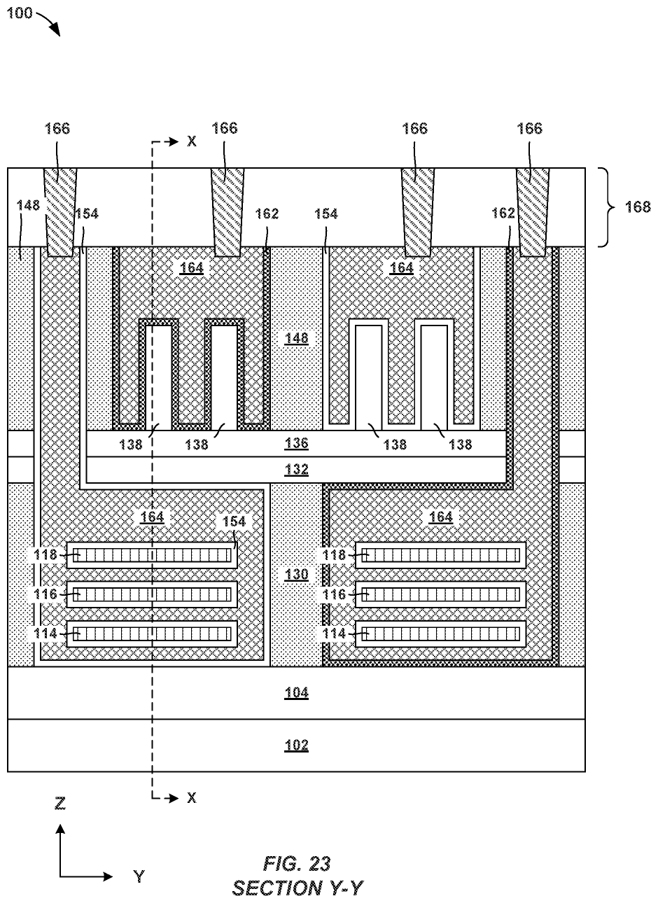

Referring now to FIGS. 22 and 23, the structure 100 is shown after forming contact structures 166 according to an embodiment of the invention. FIG. 22 depicts a cross-sectional view of the structure 100 shown in FIG. 23 taken along line X-X, and FIG. 23 depicts a cross-sectional view of the structure 100 shown in FIG. 22 taken along line Y-Y.

Another dielectric layer 168 is blanket deposited across the structure 100 and contact trenches are subsequently formed in the dielectric layer 168. The contact trenches are then filled with a conductive material to form the contact structure 166 according to known techniques. The contact structure 166 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. After, excess conductive material can be polished using known techniques until a topmost surface of the contact structure 166 is flush, or substantially flush, with topmost surfaces of the dielectric layer 168.

As illustrated in FIGS. 22 and 23, the stacked transistor structures represented by the structure 100 has some distinctive notable features. For purposes of this description the structure 100 illustrated in the figures and described herein includes two stacked transistor structures positioned adjacent, or next, to one another, and manufactured in a single replacement gate process flow. Further, each of the stacked transistor structures includes a top device and a bottom device. More specifically, both bottom devices have a nanosheet or gate-all-around structure, and both top devices have a fin structure.

In sum, the structure 100 and associated process flow enable manufacturing of stacked devices having multiple threshold voltages. Even more specifically, the threshold voltage of each device of the structure 100 can be fine-tuned or adjusted separately form one another. This is accomplished by using different gate dielectrics (154, 162) in combination with different gate materials (164). For example, with continued reference to the structure 100 of FIGS. 22 and 23, four different devices each having a different threshold voltage is achieved by forming the two different gate dielectrics and subsequently forming four different gates (164). As such, the threshold voltage for each device is individually tunable. Stated differently, each of the four devices of the structure 100 can be manufactured with a different gate dielectric and a different gate materials.

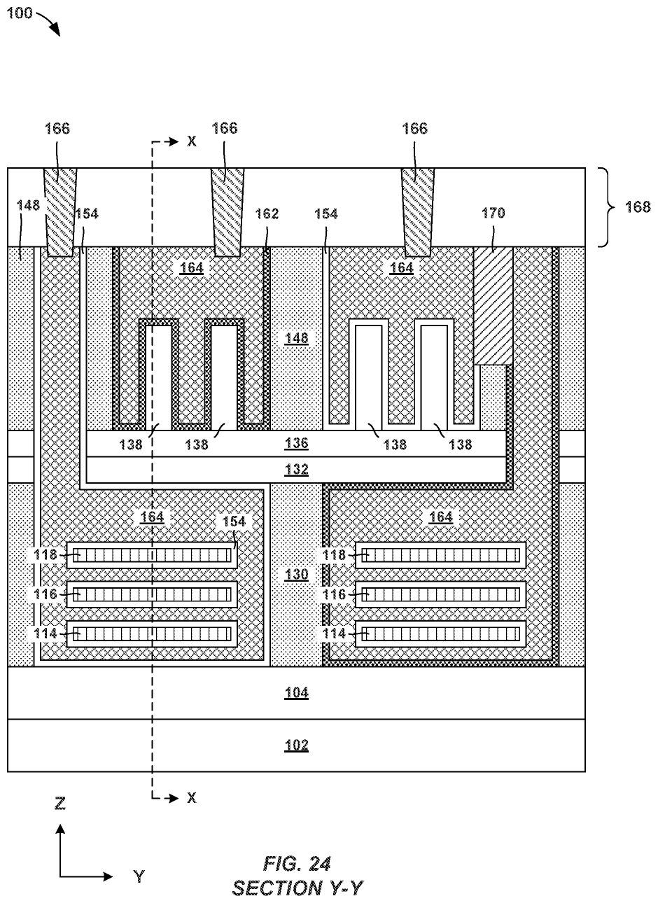

Referring now to FIG. 24, the structure 100 is shown after forming contact bridge 170 according to an alternative embodiment of the invention. In some embodiments, designers may need to connect, or wire, multiple gates together. Doing so can be accomplished with backside wiring; however, a similar effect may be accomplished in the disclosed structure by forming the contact bridge 170. Specifically, a portion of the top insulators 148 located between adjacent functional gates 164 is removed and replaced with a compatible conductive material, as shown. A contact bridge can be located between only top and bottom devices of the left stack, between only top and bottom devices of the right stack (as shown), between only top devices, or some combination thereof. The contact bridge 170 could be used to form a shared gate CMOS device. It is further noted, only a single contact (166) would be required to connect to the shared gate, as illustrated in FIG. 24.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first stacked transistor structure comprising a top device stacked directly above a bottom device; and
a second stacked transistor structure adjacent to the first stacked transistor, the second stacked transistor comprising a top device stacked directly above a bottom device;
wherein the top device of the first stacked transistor structure and the top device of the second stacked transistor structure are made from different gate dielectric materials, and
wherein the bottom device of the first stacked transistor structure and the bottom device of the second stacked transistor structure are made from different gate dielectric materials.

2. The semiconductor structure according to claim 1,
wherein the top device of the first stacked transistor structure and the top device of the second stacked transistor structure are made from different gate materials, and
wherein the bottom device of the first stacked transistor structure and the bottom device of the second stacked transistor structure are made from different gate materials.

3. The semiconductor structure according to claim 1,
wherein the top device and the bottom device of the first stacked transistor structure each have a different gate dielectric material and a different gate material.

4. The semiconductor structure according to claim 1,
wherein the top device of the first stacked transistor structure, the top device of the second stacked transistor structure, the bottom device of the first stacked transistor structure, and the bottom device of the second stacked transistor structure are made from different gate materials.

5. The semiconductor structure according to claim 1,
wherein channel regions of the top devices comprise one or more semiconductor fins, wherein a length of each semiconductor fin is measured between opposite source drain regions of the top devices,
wherein channel regions of the bottom devices comprise stacks of semiconductor nanosheets, wherein a width of each stack of semiconductor nanosheets is measured between opposite source drain regions of the bottom devices, and
wherein the length of each semiconductor fins is equal to the width of the stacks of semiconductor nanosheets.

6. The semiconductor structure according to claim 1,
wherein the top devices of both the first stacked transistor structure and the second stacked transistor structure are made from different gate dielectric materials, and
wherein the different gate dielectric materials of the top devices share at least one element.

7. The semiconductor structure according to claim 1, further comprising:
a bonding oxide layer separating the bottom devices from the top devices, wherein a portion of a gate material for each of the bottom devices extends through the bonding oxide layer.

8. A semiconductor structure comprising:
a first stacked transistor structure comprising a top device stacked directly above a bottom device; and
a second stacked transistor structure adjacent to the first stacked transistor, the second stacked transistor comprising a top device stacked directly above a bottom device;
wherein uppermost surfaces of gate structures for each of the top device of the first stacked transistor structure, the top device of the second stacked transistor structure, the bottom device of the first stacked transistor structure, and the bottom device of the second stacked transistor structure are substantially flush with one another.

9. The semiconductor structure according to claim 8,
wherein the top device of the first stacked transistor structure and the top device of the second stacked transistor structure are made from different gate materials, and
wherein the bottom device of the first stacked transistor structure and the bottom device of the second stacked transistor structure are made from different gate materials.

10. The semiconductor structure according to claim 8,
wherein the top device and the bottom device of the first stacked transistor structure each have a different gate dielectric material and a different gate material.

11. The semiconductor structure according to claim 8,
wherein the top device of the first stacked transistor structure, the top device of the second stacked transistor structure, the bottom device of the first stacked transistor structure, and the bottom device of the second stacked transistor structure are made from different gate materials.

12. The semiconductor structure according to claim 8,
wherein channel regions of the top devices comprise one or more semiconductor fins, wherein a length of each semiconductor fin is measured between opposite source drain regions of the top devices,
wherein channel regions of the bottom devices comprise stacks of semiconductor nanosheets, wherein a width of each stack of semiconductor nanosheets is measured between opposite source drain regions of the bottom devices, and
wherein the length of each semiconductor fin is equal to the width of the stacks of semiconductor nanosheets.

13. The semiconductor structure according to claim 8,
wherein the top devices of both the first stacked transistor structure and the second stacked transistor structure are made from different gate dielectric materials, and
wherein the different gate dielectric materials of the top devices share at least one element.

14. The semiconductor structure according to claim 8, further comprising:
a bonding oxide layer separating the bottom devices from the top devices, wherein a portion of a gate material for each of the bottom devices extends through the bonding oxide layer.

15. A semiconductor structure comprising:
a stacked transistor structure comprising a top device stacked directly above a bottom device, wherein the top device comprises a different threshold voltage than the bottom device, and wherein an uppermost surface of a gate metal for the top device is substantially flush with an uppermost surface of a gate metal for the bottom device.

16. The semiconductor structure according to claim 15,
wherein the top device and the bottom device have different gate materials.

17. The semiconductor structure according to claim 15,
wherein the top device and the bottom device have different gate dielectric materials.

18. The semiconductor structure according to claim 15,
wherein channel regions of the top device comprise one or more semiconductor fins, wherein a length of each semiconductor fin is measured between opposite source drain regions of the top device,
wherein channel regions of the bottom device comprise a stack of semiconductor nanosheets, wherein a width of the stack of semiconductor nanosheets is measured between opposite source drain regions of the bottom device, and
wherein the length of each the semiconductor fins is equal to the width of the stack of semiconductor nanosheets.

19. The semiconductor structure according to claim 15,
wherein the top device and the bottom device have different gate dielectric materials, and
wherein the different gate dielectric materials share at least one element.

20. The semiconductor structure according to claim 1, further comprising:
a bonding oxide layer separating the bottom device from the top device, wherein a portion of a gate material for the bottom device extends through the bonding oxide layer.
